(19) United States
(12) Patent Application Publication
(10) Pub. No.: US 2025/0109010 A1
(43) Pub. Date: Apr. 3, 2025

(54) PRESSURE VALVE FOR MICROELECTROMECHANICAL SYSTEM DIE

(71) Applicant: Knowles Electronics, LLC, Itasca, IL (US)

(72) Inventors: Faisal Zaman, Naperville, IL (US); Sung B. Lee, Chicago, IL (US); Richard Li-Chen Chen, Zhubei City (TW); Shubham Shubham, Schaumburg, IL (US); Michael Kuntzman, Chicago, IL (US); Michael Pedersen, Long Grove, IL (US)

(21) Appl. No.: 18/480,218

(22) Filed: Oct. 3, 2023

(51) Int. Cl. B81B 3/00; B81B 7/00

(52) U.S. Cl. CPC B81B 3/0072; B81B 3/0021; B81B 3/0056; B81B 7/0016; B81B 2203/053

(57) ABSTRACT

A MEMS die comprises a substrate having an opening, a diaphragm attached to the substrate around a periphery of the opening so as to cover the opening, the diaphragm having an aperture, and a backplate separated from the diaphragm and disposed on a side of the diaphragm opposite the substrate, the backplate comprising a plug that extends toward the aperture from an attached end to a free end. In an embodiment the free end of the plug has a smaller area than the aperture, and the plug is separated from the diaphragm by a gap, wherein a size of the gap determines a level of fluid communication across the diaphragm through the aperture.

### FIELD OF THE DISCLOSURE

The present disclosure relates to a valve for a microelectromechanical system (MEMS) die, and more particularly to a valve that opens to relieve reverse overpressure that could otherwise damage a diaphragm of a MEMS die.

### BACKGROUND

It is known that in the fabrication of MEMS devices often a plurality of devices are manufactured in a single batch process wherein individual portions of the batch process representative of individual MEMS devices are known as dies. Accordingly, a number of MEMS dies can be manufactured in a single batch process and then cut apart or otherwise separated for further fabrication steps or for their ultimate use, which for example without limitation includes use as an acoustic transducer or other portion of a microphone.

Physical components of a MEMS microphone, for example, a diaphragm or a backplate can experience significantly large pressure stimulus during random or controlled air-burst events. Examples of random events include accidental device drops, sudden pressure changes attributed to events like door closures, or compressed air cleaning during assembly processes. Examples of controlled events include standardized static pressure tests, drop tests, and tumble tests.

Under large pressure stimulus (for example, pressure exceeding 10 psi), components of a MEMS die can experience large deflections. As a result, large deflection-induced stress can build up at varying locations of the MEMS die, for example in the diaphragm or backplate. The concentration of the stress is geometry and pressure dependent. Beyond certain pressure levels, the fracture limits of MEMS components are exceeded, which results in catastrophic failure in terms of breakage of or irreversible cracks in the MEMS components that renders the MEMS die non-functional.

### DRAWINGS

The foregoing and other features of the present disclosure will become more fully apparent from the following description and appended claims, taken in conjunction with the accompanying drawings. These drawings depict only several embodiments in accordance with the disclosure and are, therefore, not to be considered limiting of its scope.

FIG. 1 is a schematic cross-sectional view of an exemplary MEMS die according to an embodiment illustrating a positive pressure applied to the MEMS die.

FIG. 2 is a schematic cross-sectional view of an exemplary MEMS die according to an embodiment illustrating a negative pressure applied to the MEMS die.

FIG. 3 is a schematic cross-sectional view of an exemplary MEMS die in a rest position according to an embodiment.

FIG. 4 is a schematic cross-sectional view of the MEMS die of FIG. 3 with an applied positive pressure.

FIG. 5 is a schematic cross-sectional view of the MEMS die of FIG. 3 with an applied negative pressure.

FIG. 6 illustrates exemplary numbers and configurations of apertures disposed through a diaphragm according to multiple embodiments.

FIG. 7 illustrates exemplary shapes of apertures disposed through a diaphragm according to multiple embodiments.

FIG. 8 is a schematic cross-sectional view of an exemplary MEMS die in a rest position according to another embodiment.

FIG. 9 is a schematic cross-sectional view of the MEMS die of FIG. 8 with an applied positive pressure.

FIG. 10 is a schematic cross-sectional view of the MEMS die of FIG. 8 with an applied negative pressure.

FIG. 11 is a schematic cross-sectional view of an exemplary MEMS die in a rest position according to a further embodiment.

FIG. 12 is a schematic cross-sectional view of the MEMS die of FIG. 11 with an applied negative pressure.

FIG. 13 is a schematic cross-sectional view of an exemplary MEMS die in a rest position according to yet another embodiment.

FIG. 14 is a schematic cross-sectional view of the MEMS die of FIG. 13 with an applied negative pressure.

FIG. 15 is a schematic cross-sectional view of a microphone assembly according to an embodiment.

### DETAILED DESCRIPTION

According to an embodiment, a MEMS die comprises a substrate having an opening, a diaphragm attached to the substrate around a periphery of the opening so as to cover the opening, the diaphragm having an aperture, and a backplate separated from the diaphragm and disposed on a side of the diaphragm opposite the substrate, the backplate comprising a plug that extends toward the aperture from an attached end to a free end. In an embodiment the free end of the plug has a smaller area than the aperture, and the plug is separated from the diaphragm by a gap, wherein a size of the gap determines a level of fluid communication across the diaphragm through the aperture. In an embodiment the plug extends into the aperture when the diaphragm is in a rest position. In an embodiment the rest position of the diaphragm relative to the backplate is achieved by application of an electrostatic bias voltage between the backplate and diaphragm. In an embodiment the rest position of the diaphragm relative to the backplate is achieved by tuning residual stress of the diaphragm, or the backplate, or both during manufacturing.

According to an embodiment the plug is tapered, having a cross-sectional area that increases going away from the free end, wherein the size of the gap gets smaller when the diaphragm moves toward the backplate, thereby decreasing the level of fluid communication through the diaphragm in response to a positive pressure, and wherein the size of the gap gets larger when the diaphragm moves away from the backplate, thereby increasing the level of fluid communication through the diaphragm in response to a negative pressure. In an embodiment the plug comprises a member that extends between the backplate and a solid cylindrical end comprising a circumferential surface oriented orthogonal to the backplate, wherein the circumferential surface is at least partly disposed within the aperture when the diaphragm is in a rest position. In an embodiment the size of the gap gets larger when the diaphragm moves away from the backplate and beyond the circumferential surface, thereby increasing the level of fluid communication through the diaphragm in response to a negative pressure, and the size of the gap gets larger when the diaphragm moves toward the backplate and beyond the circumferential surface, thereby increasing the level of fluid communication through the diaphragm in response to a positive pressure.

In an embodiment, a MEMS die comprises a substrate having an opening, a diaphragm attached to the substrate around a periphery of the opening so as to cover the opening, the diaphragm having an aperture, and a backplate separated from the diaphragm and disposed on a side of the diaphragm opposite the substrate, the backplate comprising a plug that extends toward the aperture from an attached end to a free end. In an embodiment the free end of the plug has a larger area than the aperture. In an embodiment the diaphragm in the rest position is in contact with the free end, and in response to a negative pressure the diaphragm moves away from the free end allowing fluid communication across the diaphragm through the aperture.

In an embodiment, a MEMS die comprises a substrate having an opening, a diaphragm attached to the substrate around a periphery of the opening so as to cover the opening, the diaphragm having an aperture, and a backplate separated from the diaphragm and disposed on a side of the diaphragm opposite the substrate, the backplate comprising a plug that extends toward the aperture from an attached end to a free end. In an embodiment the free end of the plug has a larger area than the aperture, wherein the free end of the plug has a pierce that allows for fluid communication through the backplate and the aperture. In an embodiment the diaphragm in the rest position is in contact with the free end, and in response to a negative pressure the diaphragm moves away from the free end allowing additional fluid communication across the diaphragm through the aperture.

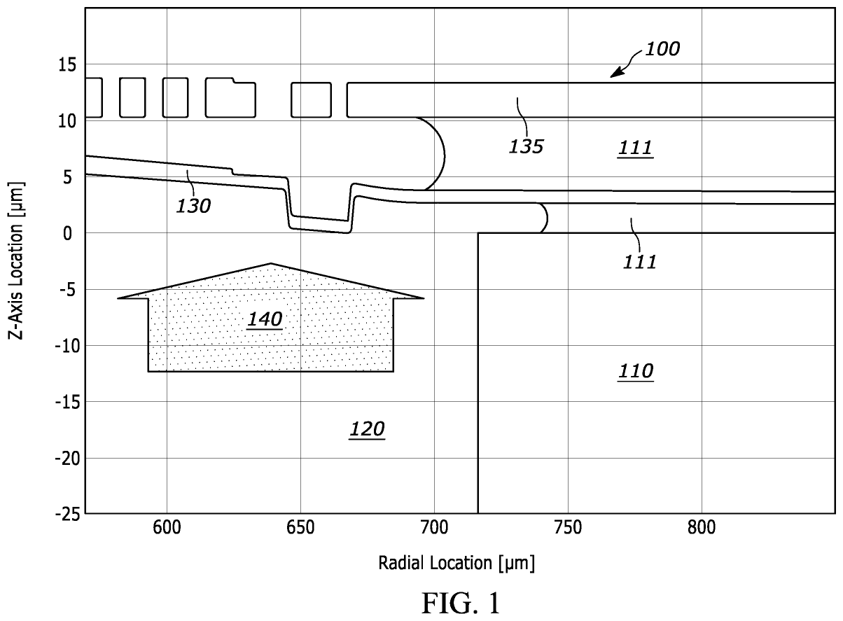

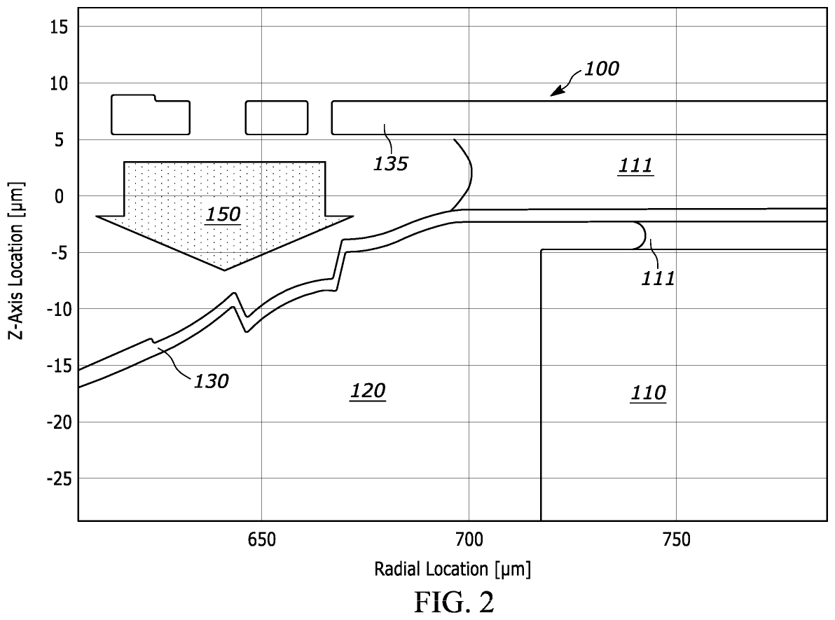

Referring to FIGS. 1 and 2, a cross-sectional schematic view of a portion of an exemplary MEMS die 100 is illustrated. The MEMS die 100 or any of the MEMS dies 100, 200, 300, 400 described herein can be used, for example without limitation as part of a microphone, a motion sensor, or other device. In an embodiment the MEMS die 100 comprises a substrate 110 having an opening 120, and a diaphragm 130 attached to the substrate 110 around a periphery of the opening 120 so as to cover the opening 120. A backplate 135 is separated from the diaphragm 130 and disposed on a side of the diaphragm 130 opposite the substrate 110. Referring to FIG. 1, positive pressure as indicated by the block arrow 140 pushes the diaphragm 130 toward the backplate 135. Referring to FIG. 2, negative pressure as indicated by the block arrow 150 pushes the diaphragm 130 away from the backplate 135.

It has been observed through extensive empirical studies across multiple platforms that a MEMS microphone diaphragm, for example the diaphragm 130, suffers failure at lower amplitudes of negative pressure 150 than positive pressure 140. This is because in the case of positive pressure 140, the backplate 135 provides structural support for the diaphragm 130. In the case of negative pressure 150, the diaphragm 130 is unable to rely on the backplate 135 for support.

A valve that is fully described hereinbelow is implemented in several embodiments. The valve opens to reduce negative pressure 150, which reduces the maximum stress in the diaphragm 130 to a level below a predetermined stress limit that would otherwise damage the diaphragm 130. By reducing the negative pressure 150, it is possible to improve survivability of the diaphragm 130. In an embodiment the valve is implemented using features constructed with the backplate 135 that would otherwise already exist, which represents a novel method of valve implementation that previously was constructed on the diaphragm 130.

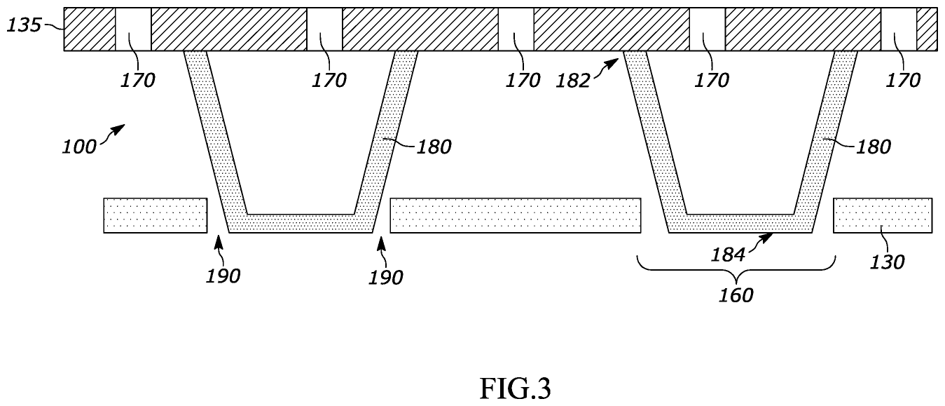

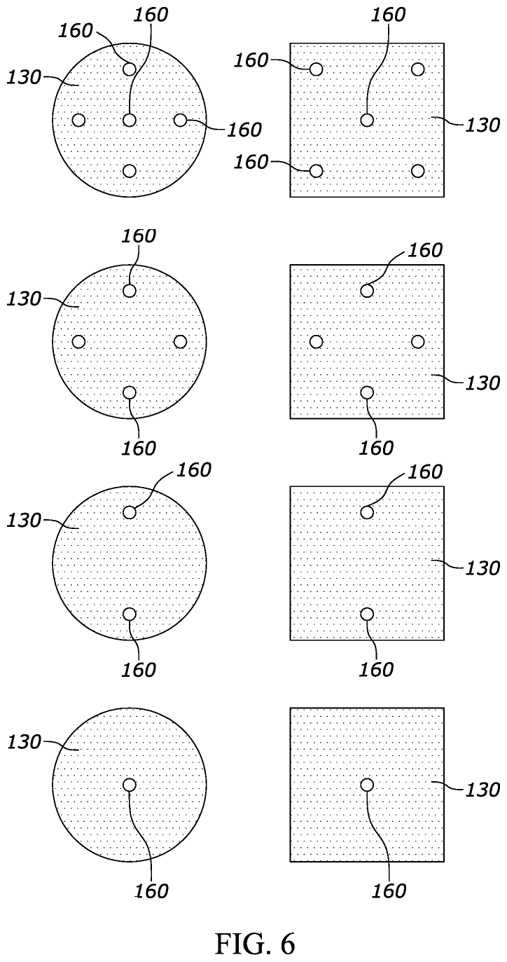

Referring to FIGS. 3-5, in an embodiment of the MEMS die 100 the diaphragm 130 includes one or more apertures 160. In an embodiment the one or more apertures 160 can be located anywhere on the diaphragm 130 relative to a center or an outer edge of the diaphragm 130. Referring briefly to FIG. 6, several exemplary configurations without limitation are shown for the one or more apertures 160 disposed through the diaphragm 130, which is illustrated to be round on the left side of FIG. 6 and square on the right side of FIG. 6. Non-limiting examples of the actual number of and configurations for the one or more apertures 160 are provided in FIG. 6; however, all of the possibilities far too numerous to include on figures herein. Similarly, the shape of the diaphragm 130 viewed in plan view can be round or square as shown, or any shape as desired, but all of the possibilities for shapes of the diaphragm 130 are far too numerous to include on figures herein.

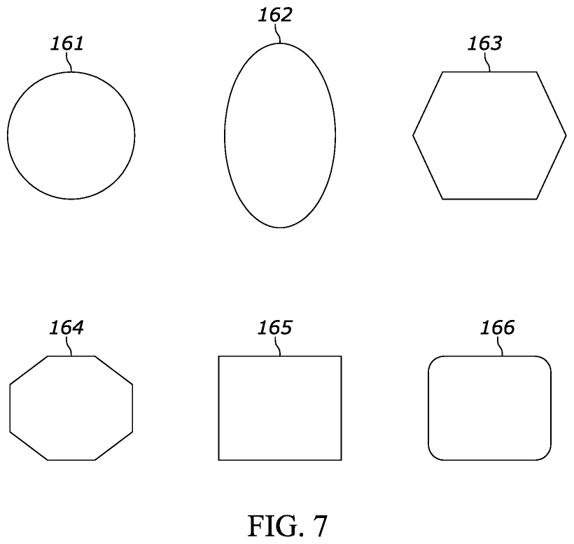

Referring briefly to FIG. 7, each of the apertures 160 can further have any cross-sectional shape as desired. For example without limitation the shape of the aperture 160 can be round 161, elliptical 162, hexagonal 163, octagonal 164, square 165, square with rounded corners 166, or any other regular or irregular polygonal shape as is desired. Although non-limiting examples of shapes for the one or more apertures 160 are provided in FIG. 7, all of the possibilities are far too numerous to include on figures herein.

Referring again to FIGS. 3-5, in an embodiment the backplate 135 includes one or more holes 170. In an embodiment the backplate 135 comprises one or more plugs 180 each extending toward one of the one or more apertures 160 from an attached end 182 to a free end 184. In an embodiment the free end 184 of each plug 180 has a smaller cross-sectional area A than the cross-sectional area B of the aperture 160 toward which it extends. In an embodiment each plug 180 is separated from the diaphragm 130 by a gap 190, wherein each gap 190 has a size that is determined by the position of each plug 180 relative to the diaphragm 130. In an embodiment the size of the each gap 190 determines the level of fluid communication across the diaphragm 130 through each aperture 160.

In an embodiment as illustrated in FIG. 3, the diaphragm 130 is illustrated in an exemplary rest position. In an embodiment when the diaphragm 130 is in the rest position each plug 180 extends into the aperture 160 toward which it extends. In an embodiment the rest position of the diaphragm 130 is achieved by application of an electrostatic bias voltage between the backplate 135 and the diaphragm 130. In an embodiment the rest position of the diaphragm 130 relative to the backplate 135 can be adjusted by changing the level of the applied electrostatic bias voltage. In an embodiment the rest position of the diaphragm 130 relative to the backplate 135 is achieved by tuning residual stress of the diaphragm 130, or the backplate 135, or both during manufacturing.

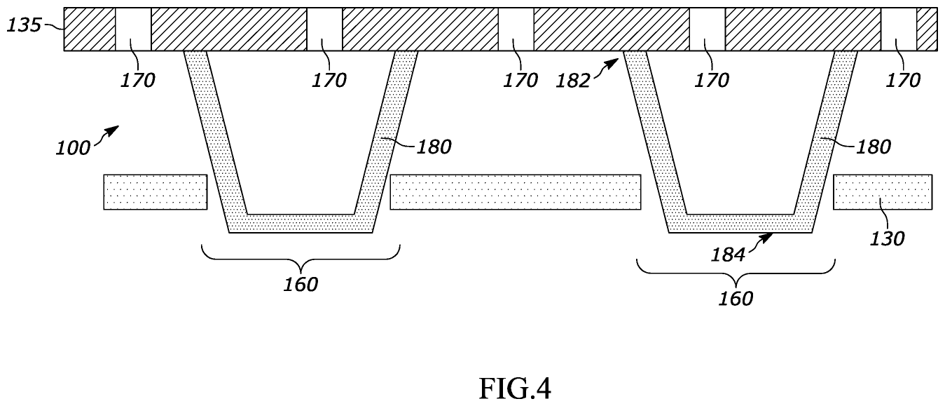

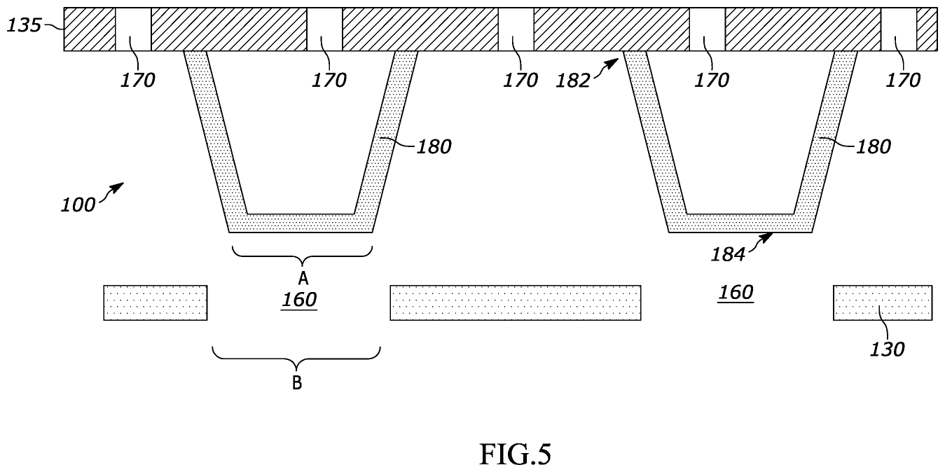

Referring to FIGS. 3-5 in an embodiment each plug 180 is tapered, having a cross-sectional area that increases going away from the free end 184. In an embodiment a positive pressure applied to the diaphragm 130 moves the diaphragm 130 towards the backplate 135. Therefore, as shown in FIG. 4, in response to a positive pressure the size of each gap 190 gets smaller when the diaphragm 130 moves toward the backplate 135, thereby decreasing the level of fluid communication through the diaphragm 130. In an embodiment a negative pressure applied to the diaphragm 130 moves the diaphragm 130 away from the backplate 135. Therefore, as shown in FIG. 5, in response to a negative pressure the size of each gap 190 gets larger when the diaphragm 130 moves away from the backplate 135, thereby increasing the level of fluid communication through the diaphragm 130.

Thus, each plug 180 and the aperture 160 toward which it extends together act as a valve having a gap 190 representing the valve opening. An increase in the size of the gap 190 between each plug 180 and associated aperture 160 in response to negative pressure on the diaphragm 130 represents an opening of the valve. Opening the valve increases the level of fluid communication through the diaphragm 130, thereby reducing the effect of the applied negative pressure and the resulting stress in the diaphragm 130. In an embodiment each valve opens to reduce the maximum stress in the diaphragm 130 to a level below a predetermined stress limit that would otherwise damage the diaphragm 130, thereby improving survivability of the diaphragm 130.

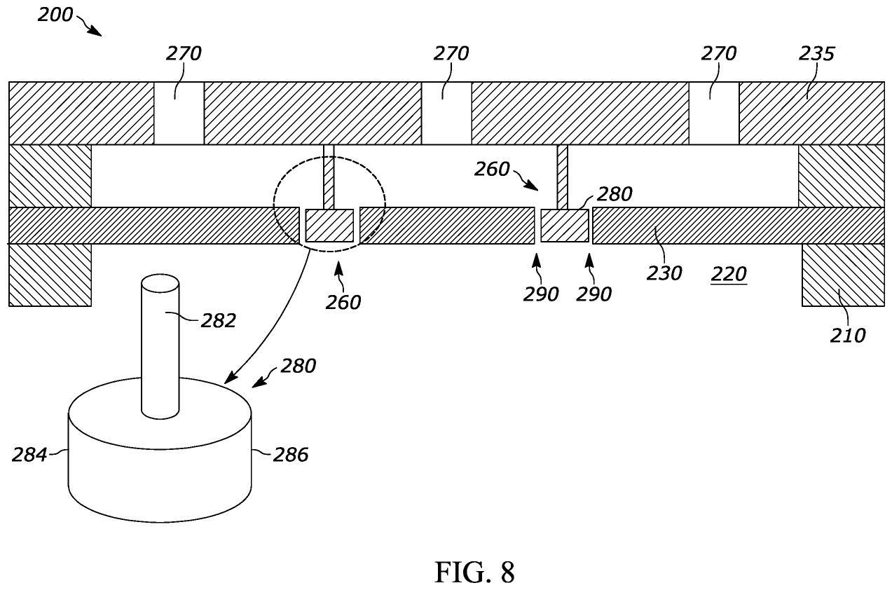

Referring to FIGS. 8-10, a cross-sectional schematic view of an exemplary MEMS die 200 is illustrated. In an embodiment the MEMS die 200 comprises a substrate 210 having an opening 220, and a diaphragm 230 attached to the substrate 210 around a periphery of the opening 220 so as to cover the opening 220. A backplate 235 is separated from the diaphragm 230 and disposed on a side of the diaphragm 230 opposite the substrate 210. In an embodiment the diaphragm 230 includes one or more apertures 260. Like the one or more apertures 160 and the diaphragm 130 discussed hereinabove with regard to FIGS. 6 and 7, in an embodiment the one or more apertures 260 can be located anywhere on the diaphragm 230 relative to a center or an outer edge of the diaphragm 230. In an embodiment the backplate 235 includes one or more holes 270.

In an embodiment the backplate 235 comprises one or more plugs 280 each extending toward one of the one or more apertures 260. Referring to FIG. 8, an embodiment of the plug 280 as shown enlarged comprises a member 282 that extends between the backplate 235 and a solid cylindrical end 284 comprising a circumferential surface 286 oriented orthogonal to the backplate 235. In an embodiment each plug 280 is separated from the diaphragm 230 by a gap 290, wherein each gap 290 has a size that is determined by the position of each solid cylindrical end 284 relative to the diaphragm 230. In an embodiment the size of the each gap 290 determines the level of fluid communication across the diaphragm 230 through each aperture 260.

Still referring to FIG. 8, the diaphragm 230 is illustrated in an exemplary rest position. In an embodiment when the diaphragm 230 is in the rest position the circumferential surface 286 of each plug 280 is at least partly disposed within the aperture 260 toward which the plug 280 extends. In an embodiment the rest position of the diaphragm 230 is achieved by application of an electrostatic bias voltage between the backplate 235 and the diaphragm 230. In an embodiment the rest position of the diaphragm 230 relative to the backplate 235 can be adjusted by changing the level of the applied electrostatic bias voltage. In an embodiment the rest position of the diaphragm 230 relative to the backplate 235 is achieved by tuning residual stress of the diaphragm 230, or the backplate 235, or both during manufacturing.

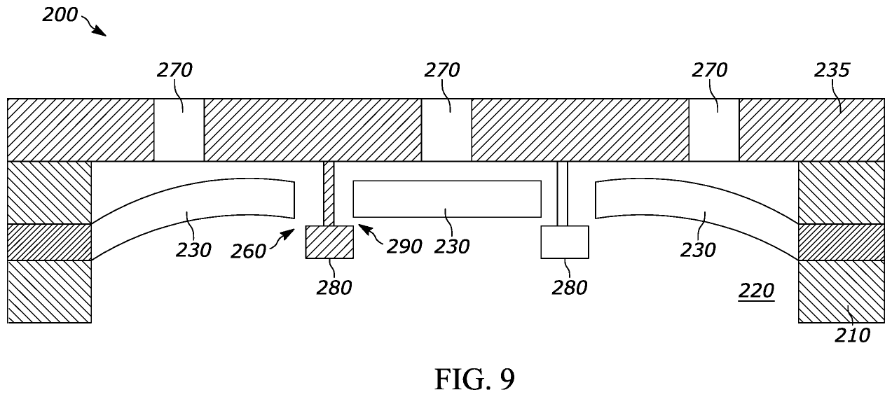

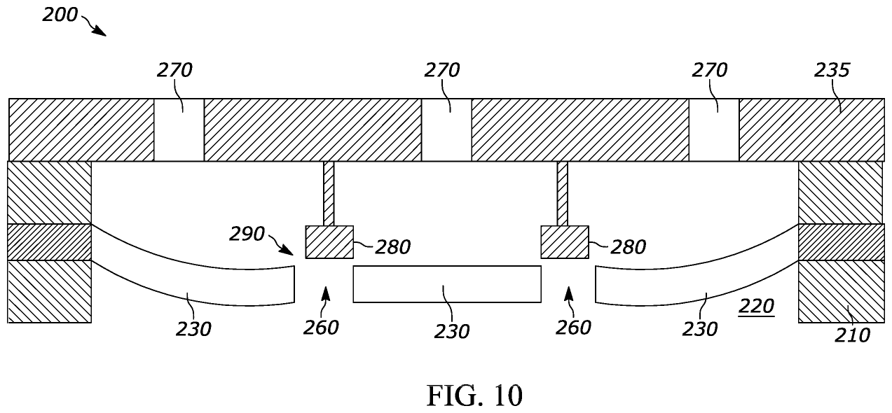

In an embodiment a positive pressure applied to the diaphragm 230 moves the diaphragm 230 towards the backplate 235. In an embodiment the size of the gap 290 gets larger when the diaphragm 230 moves toward the backplate 235 and beyond the circumferential surface 286 as shown in FIG. 9, thereby increasing the level of fluid communication through the diaphragm 230 in response to a positive pressure. In an embodiment a negative pressure applied to the diaphragm 230 moves the diaphragm 230 away from the backplate 235. In an embodiment the size of the gap 290 gets larger when the diaphragm 230 moves away from the backplate 235 and beyond the circumferential surface 286 as shown in FIG. 10, thereby increasing the level of fluid communication through the diaphragm 230 in response to a negative pressure.

Thus, each plug 280 and the aperture 260 toward which it extends together act as a valve having a gap 290 representing the valve opening. An increase in the size of the gap 290 between each plug 280 and associated aperture 260 in response to negative or positive pressure on the diaphragm 230 represents an opening of the valve. Opening the valve increases the level of fluid communication through the diaphragm 230, thereby reducing the effect of the applied negative or positive pressure and the resulting stress in the diaphragm 230. In an embodiment each valve opens to reduce the maximum stress in the diaphragm 230 to a level below a predetermined stress limit that would otherwise damage the diaphragm 230, thereby improving survivability of the diaphragm 230.

In the embodiments of the MEMS die 100, 200 described hereinabove the diaphragm 130, 230 remains in close proximity with the one or more plugs 180, 280 during normal operating conditions. In these embodiments the gaps 190, 290 during normal operating conditions are small enough to inhibit contamination via particle or water ingress through the gaps 190, 290.

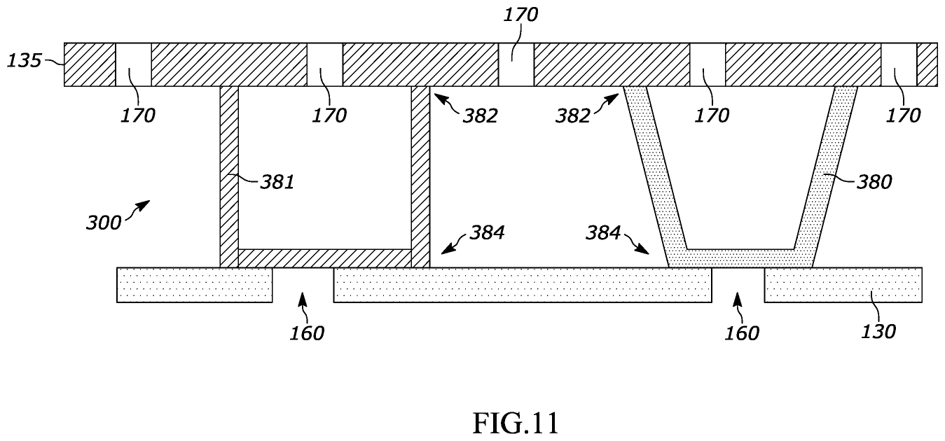

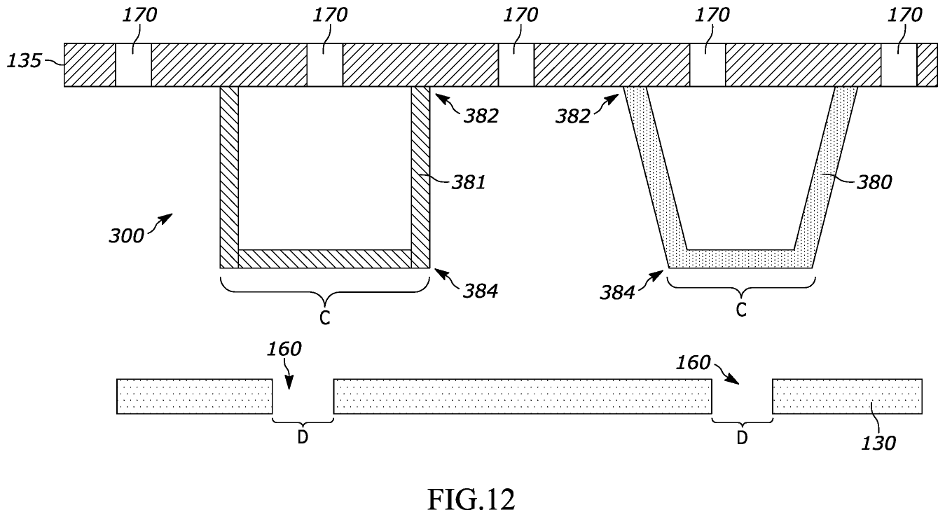

Referring to FIGS. 11 and 12, a cross-sectional schematic view of an exemplary MEMS die 300 is illustrated. In an embodiment the MEMS die 300 includes many structural components in common with the MEMS die 100 as shown in FIGS. 1-5. For example, the MEMS die 300 comprises a substrate 110 having an opening 120, and a diaphragm 130 attached to the substrate 110 around a periphery of the opening 120 so as to cover the opening 120. A backplate 135 is separated from the diaphragm 130 and disposed on a side of the diaphragm 130 opposite the substrate 110. In an embodiment the diaphragm 130 includes one or more apertures 160. As discussed hereinabove with regard to FIGS. 6 and 7, in an embodiment the one or more apertures 160 can be located anywhere on the diaphragm 130 relative to a center or an outer edge of the diaphragm 130. In an embodiment the backplate 135 includes one or more holes 170.

However, the embodiment of the MEMS die 300 illustrated in FIGS. 11 and 12 differs from the prior described embodiments in the following ways. In an embodiment the backplate 135 of the MEMS die 300 further comprises one or more plugs 380, 381 each extending toward one of the one or more apertures 160 from an attached end 382 to a free end 384. In an embodiment each plug 381 has a constant or uniform cross-sectional area from the attached end 382 to the free end 384 as shown by the plug 381 on the left in FIGS. 11 and 12. In another embodiment each plug 380 is tapered so that a cross-sectional area of the plug 380 increases going away from the free end 384 as shown by the plug 380 on the right in FIGS. 11 and 12.

In an embodiment the free end 384 of each plug 380, 381 has a larger cross-sectional area C than the cross-sectional area D of the aperture 160 toward which it extends. In an embodiment as illustrated in FIG. 11, the diaphragm 130 is illustrated in an exemplary rest position wherein the diaphragm 130 is in contact with the free end (or free ends) 384 of the one or more plugs 380, 381. As noted hereinabove, in an embodiment the rest position of the diaphragm 130 is achieved by application of an electrostatic bias voltage between the backplate 135 and the diaphragm 130. In an embodiment the rest position of the diaphragm 130 relative to the backplate 135 can be adjusted by changing the level of the applied electrostatic bias voltage. In an embodiment the rest position of the diaphragm 130 relative to the backplate 135 is achieved by tuning residual stress of the diaphragm 130, or the backplate 135, or both during manufacturing.

In this embodiment because the diaphragm 130 in the rest position makes contact with the free end (or free ends) 384 of the one or more plugs 380, 381, a positive pressure applied to the diaphragm 130 deflects portions of the diaphragm 130 not making contact toward the backplate 135, but the portions of the diaphragm 130 making contact remain in contact. In an embodiment a negative pressure applied to the diaphragm 130 moves the diaphragm 130 away from the backplate 135. Therefore, as illustrated in FIG. 12, in response to a negative pressure the diaphragm 130 moves away from the free end (or free ends) 384 of the one or more plugs 380, 381 allowing fluid communication across the diaphragm 130 through the one or more apertures 160. Thus, each plug 380, 381 and the aperture 160 toward which it extends together act as a valve wherein motion of the diaphragm 130 away from the backplate 135 in response to negative pressure on the diaphragm 130 represents an opening of the valve. Opening the valve allows fluid communication through the diaphragm 130, thereby reducing the effect of the applied negative pressure and the resulting stress in the diaphragm 130. In an embodiment each valve opens to reduce the maximum stress in the diaphragm 130 to a level below a predetermined stress limit that would otherwise damage the diaphragm 130, thereby improving survivability of the diaphragm 130.

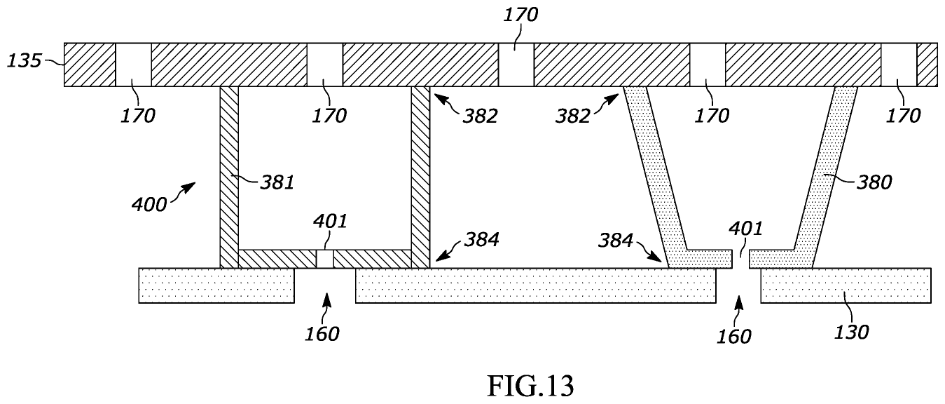

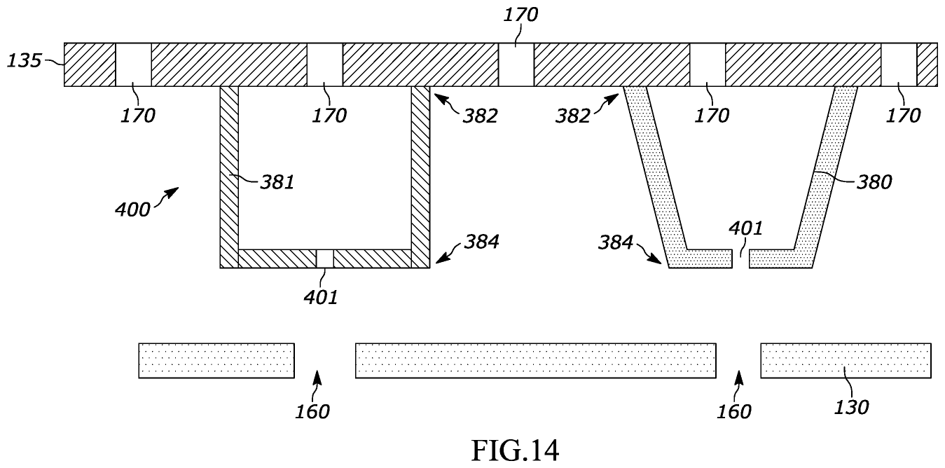

Referring to FIGS. 13 and 14, a cross-sectional schematic view of an exemplary MEMS die 400 is illustrated. The MEMS die 400 illustrated in FIGS. 13 and 14 is substantially the same as the MEMS die 300 described in regard to FIGS. 11 and 12, but differs by further comprising a pierce 401 disposed through the free end (or free ends) 384 of the one or more plugs 380, 381. The pierce 401 disposed through the one or more plugs 380, 381 allows for fluid communication through the backplate 135 and the aperture 160 toward which the one or more plugs 380, 381 extends. In this embodiment, in response to a negative pressure the diaphragm 130 moves away from the free end (or free ends) 384 of the one or more plugs 380, 381 allowing additional fluid communication across the diaphragm 130 through the aperture 160.

Thus, each plug 380, 381 and the aperture 160 toward which it extends together act as a valve having the pierce 401 for an opening. Motion of the diaphragm 130 away from the backplate 135 in response to negative pressure on the diaphragm 130 represents a further opening of the valve, which allows additional fluid communication through the diaphragm 130, thereby reducing the effect of the applied negative pressure and the resulting stress in the diaphragm 130. In an embodiment each valve opens additionally beyond the opening of the pierce 401 to reduce the maximum stress in the diaphragm 130 to a level below a predetermined stress limit that would otherwise damage the diaphragm 130, thereby improving survivability of the diaphragm 130.

In an embodiment, materials used for the substrate 110, 210 can, for example without limitation, include silicon, glass, gallium arsenide (GaAs), and polysilicon. In an embodiment, materials used for the diaphragm 130, 230 and the backplate 135, 235 can, for example without limitation, include silicon, polysilicon, gallium arsenide (GaAs), silicon dioxide (SiO₂), tetraethyl orthosilicate (TEOS), silicon nitride (SiN), silicon oxynitride (SiON), and metal or other metal compounds. In each of the described embodiments the diaphragm 130, 230 is separated from the backplate 135, 235 and from the substrate 110, 210 by spacers 111 (for example, see FIG. 1), wherein the spacers 111 can be made from sacrificial materials, for example without limitation, TEOS Oxide or other sacrificial materials.

During operation of any of the embodiments of the MEMS die 100, 200, 300, 400 for example without limitation as an acoustic transducer, electric charge is applied to the backplate 135, 235 and to the diaphragm 130, 230 thereby inducing an electric field between therebetween. Movement of air (e.g., resulting from sound waves) pushes against the surface of the diaphragm 130, 230 facing the opening 120, 220 causing the diaphragm 130, 230 to deflect (enter a deflection state) and to deform. This deformation causes a change in the capacitance between the backplate 135, 235 and the diaphragm 130, 230 which can be detected and interpreted as sound.

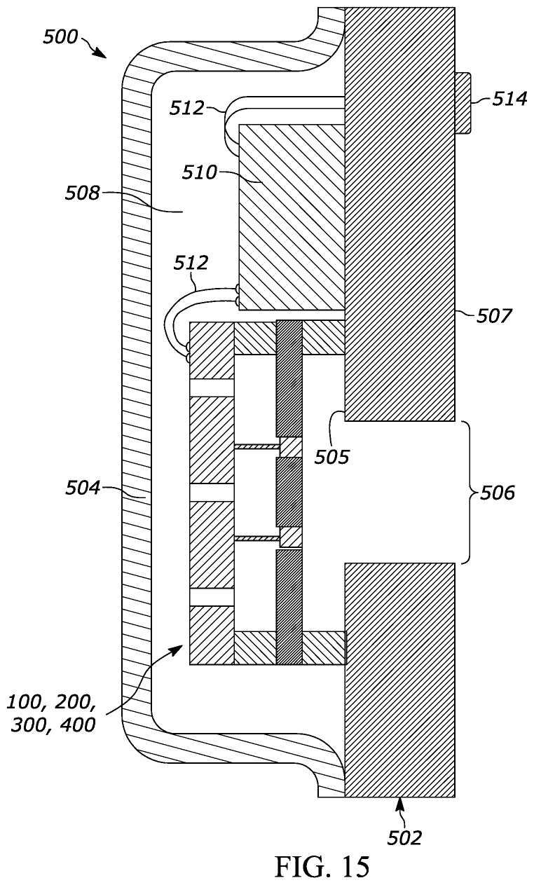

Referring to FIG. 15, in an exemplary embodiment the MEMS die 100, 200, 300, 400 used, for example without limitation as an acoustic transducer is configured to fit within a microphone assembly, generally labeled 500. In an embodiment the assembly 500 includes a housing including a base 502 having a first surface 505 and an opposing second surface 507. In an embodiment the housing further includes a cover 504 (e.g., a housing lid), and an acoustic port 506. In an embodiment the port 506 extends between the first surface 505 and the second surface 507. In one exemplary implementation, the base 502 is a printed circuit board. In an embodiment the cover 504 is coupled to the base 502 (e.g., the cover 504 may be mounted onto a peripheral edge of the base 502). In an embodiment the cover 504 and the base 502 together form an enclosed volume 508 for the assembly 500.

As shown in FIG. 15, in an embodiment the acoustic port 506 is disposed on the base 502 and is structured to convey sound waves to the MEMS die 100, 200, 300, 400 used as an acoustic transducer located within the enclosed volume 508. In other implementations, the acoustic port 506 is disposed on the cover 504 and/or a side wall of the cover 504. In some embodiments, the assembly 500 forms part of a compact computing device (e.g., a portable communication device, a smartphone, a smart speaker, an internet of things (IoT) device, etc.), where one, two, three or more assemblies may be integrated for picking-up and processing various types of acoustic signals such as speech and music.

In an embodiment the assembly 500 includes an electrical circuit disposed within the enclosed volume 508. In an embodiment, the electrical circuit includes an integrated circuit (IC) 510. In an embodiment the IC 510 is disposed on the first surface 505 of the base 502. The IC 510 may be an application specific integrated circuit (ASIC). Alternatively, the IC 510 may include a semiconductor die integrating various analog, analog-to-digital, and/or digital circuits. In an embodiment the cover 504 is disposed over the first surface 505 of the base 502 covering the MEMS die 100, 200, 300, 400 and the IC 510.

In the assembly 500 of FIG. 15, the MEMS die 100, 200, 300, 400 is illustrated as being disposed on the first surface 505 of the base 502. When used as a MEMS acoustic transducer, the MEMS die 100, 200, 300, 400 converts sound waves, received through acoustic port 506, into a corresponding electrical microphone signal, and generates an electrical signal (e.g., a voltage) at a transducer output in response to acoustic activity incident on the port 506. As shown in FIG. 15, the transducer output includes a pad or terminal of the transducer that is electrically connected to the electrical circuit via one or more bonding wires 512. The assembly 500 of FIG. 15 further includes one or more electrical contacts, shown schematically as contacts 514, typically disposed on a bottom surface of the base 502. The contacts 514 are electrically coupled to the electrical circuit. The contacts 514 are configured to electrically connect the assembly 500 to one of a variety of host devices.

Steps in a production process utilized to produce any of the MEMS dies 100, 200, 300, 400 as described hereinabove include deposition, etching, masking, patterning, and/or cutting. All of the steps are not described in detail herein. The foregoing description of illustrative embodiments has been presented for purposes of illustration and of description. It is not intended to be exhaustive or limiting with respect to the precise form disclosed, and modifications and variations are possible in light of the above teachings or may be acquired from practice of the disclosed embodiments. It is intended that the scope of the disclosure be defined by the claims appended hereto and their equivalents.

What is claimed is:

1. A microelectromechanical system (MEMS) die, comprising:
a substrate having an opening;
a diaphragm attached to the substrate around a periphery of the opening so as to cover the opening, the diaphragm having an aperture; and
a backplate separated from the diaphragm and disposed on a side of the diaphragm opposite the substrate, the backplate comprising a plug that extends toward the aperture from an attached end to a free end;
wherein the free end of the plug has a smaller area than the aperture, and the plug is separated from the diaphragm by a gap; and
wherein a size of the gap determines a level of fluid communication across the diaphragm through the aperture.

2. The MEMS die of claim 1, wherein the plug extends into the aperture when the diaphragm is in a rest position.

3. The MEMS die of claim 2, wherein the rest position of the diaphragm relative to the backplate is achieved by application of an electrostatic bias voltage between the backplate and diaphragm.

4. The MEMS die of claim 2, wherein the rest position of the diaphragm relative to the backplate is achieved by tuning residual stress of the diaphragm, or the backplate, or both during manufacturing.

5. The MEMS die of claim 1, wherein the plug is tapered, having a cross-sectional area that increases going away from the free end.

6. The MEMS die of claim 5, wherein the size of the gap gets smaller when the diaphragm moves toward the backplate, thereby decreasing the level of fluid communication through the diaphragm in response to a positive pressure.

7. The MEMS die of claim 5, wherein the size of the gap gets larger when the diaphragm moves away from the backplate, thereby increasing the level of fluid communication through the diaphragm in response to a negative pressure.

8. The MEMS die of claim 1, wherein the plug comprises a member that extends between the backplate and a solid cylindrical end comprising a circumferential surface oriented orthogonal to the backplate.

9. The MEMS die of claim 8, wherein the circumferential surface is at least partly disposed within the aperture when the diaphragm is in a rest position.

10. The MEMS die of claim 9, wherein the size of the gap gets larger when the diaphragm moves away from the backplate and beyond the circumferential surface, thereby increasing the level of fluid communication through the diaphragm in response to a negative pressure.

11. The MEMS die of claim 9, wherein the size of the gap gets larger when the diaphragm moves toward the backplate and beyond the circumferential surface, thereby increasing the level of fluid communication through the diaphragm in response to a positive pressure.

12. A microelectromechanical system (MEMS) die, comprising:
a substrate having an opening;
a diaphragm attached to the substrate around a periphery of the opening so as to cover the opening, the diaphragm having an aperture; and
a backplate separated from the diaphragm and disposed on a side of the diaphragm opposite the substrate, the backplate comprising a plug that extends toward the aperture from an attached end to a free end;
wherein the free end of the plug has a larger area than the aperture.

13. The MEMS die of claim 12, wherein the diaphragm in the rest position is in contact with the free end.

14. The MEMS die of claim 13, wherein in response to a negative pressure the diaphragm moves away from the free end allowing fluid communication across the diaphragm through the aperture.

15. The MEMS die of claim 13, wherein the rest position of the diaphragm relative to the backplate is achieved by application of an electrostatic bias voltage between the backplate and diaphragm.

16. The MEMS die of claim 13, wherein the rest position of the diaphragm relative to the backplate is achieved by tuning residual stress of the diaphragm, or the backplate, or both during manufacturing.

17. A microelectromechanical system (MEMS) die, comprising:
a substrate having an opening;
a diaphragm attached to the substrate around a periphery of the opening so as to cover the opening, the diaphragm having an aperture; and
a backplate separated from the diaphragm and disposed on a side of the diaphragm opposite the substrate, the backplate comprising a plug that extends toward the aperture from an attached end to a free end;
wherein the free end of the plug has a larger area than the aperture; and
wherein the free end of the plug has a pierce that allows for fluid communication through the backplate and the aperture.

18. The MEMS die of claim 17, wherein the diaphragm in the rest position is in contact with the free end.

19. The MEMS die of claim 18, wherein in response to a negative pressure the diaphragm moves away from the free end allowing additional fluid communication across the diaphragm through the aperture.

20. The MEMS die of claim 17, wherein the rest position of the diaphragm relative to the backplate is achieved by application of an electrostatic bias voltage between the backplate and diaphragm or by tuning residual stress of the diaphragm, or the backplate, or both during manufacturing.
